(19) United States
(12) Patent Application Publication
(10) Pub. No.: US 2007/0074652 A1
(43) Pub. Date: Apr. 5, 2007

(54) Method for epitaxy with low thermal budget and use thereof

(75) Inventors: Didier Dutartre, Meylan (FR); Nicolas Loubet, Grenoble (FR); Alexandre Talbot, Grenoble (FR)

Correspondence Address: GRAYBEAL JACKSON HALEY LLP, Suite 350, 155-108th Avenue N.E., Bellevue, WA, 98004-5973, US

(73) Assignee: STMicroelectronics SA

(21) Appl. No.: 11/523,824

(22) Filed: Sep. 14, 2006

(30) Foreign Application Priority Data
Sep. 14, 2005 (FR) 05 09 397

(51) Int. Cl. C30B 23/00; C30B 25/00; C30B 28/12; C30B 28/14

(52) U.S. Cl. 117/89

(57) ABSTRACT

A method for low-temperature epitaxy at the surface of at least one plate made of a pure silicon- or silicon alloy (SiGe, SiC, SiGeC . . . )-based material, in a chemical vapor deposition (CVD) system, in particular a rapid thermal (RTCVD) system, which method includes the following steps: loading the plate into the equipment, at a loading temperature, preparing the surface for the deposition of new chemical species, and after preparing the surface, performing the deposition under low-temperature epitaxy conditions (>750° C.), in which method the preparation of the surface includes a step of passivation of the surface by injection of an active gas, or gas mixture.

### PRIORITY CLAM

This application claims priority from French patent application No. 05 09 397, filed Sep. 14, 2005, which is incorporated herein by reference.

### TECHNICAL FIELD

An embodiment of this invention relates to epitaxy methods performed by chemical vapor deposition (CVD), in particular in the production of printed circuits, on a silicon-based material (pure silicon or silicon alloy).

More specifically, it relates to so-called low-temperature methods (<700° C.), in particular implemented in so-called rapid thermal chemical vapor deposition systems.

### BACKGROUND

In general, it is recognized that epitaxy by CVD is limited to high-temperature fields because at moderate temperatures, the growth of new species on a silicon-based plate is limited by the presence of silica (SiO2) at the surface of the plate, usually resulting in the presence of water vapor in the CVD equipment (reactor).

In addition, other chemical species, hydrocarbons, for example, are capable of contaminating the plate and therefore require cleaning.

A number of techniques are known for cleaning the surface of a plate, in particular in order to remove oxides, for example by hydrofluoric acid treatment. However, even with treatments such as this, contamination of the surface of the plate is still possible. This is why, conventionally, a step of annealing, preferably under hydrogen, prior to the actual deposition, is always used.

The term annealing is used to refer to a step in which the plate is subjected, for a certain amount of time, before the deposition, to a temperature greater than or equal to that of the deposition.

This annealing is performed either at a high temperature (>1000° C.) when a chemical oxide resulting from a preliminary cleaning step, for example in RCA-type wet chemistry (solution of hydrogen peroxide and ammonia), is present on the silicon surface; or at a more moderate temperature (850-950° C.) when the silicon surface has been fully deoxidized, for example by an “HF-last”-type hydrofluoric acid treatment, i.e. by applying hydrofluoric acid in the last chemical step, possibly followed by rinsing and drying.

Indeed, the chemical attack rate of silica (SiO2) under hydrogen decreases with temperature. It is therefore almost impossible to totally eliminate the oxides resulting from an RCA treatment at temperatures less than 1000° C.

The conventional low-temperature epitaxy methods for plates in which structures may already be present on the surface that cannot withstand high-temperature annealing, therefore use an ex situ “HF-last”-type treatment, which removes the oxides from the surface and temporarily passivate this surface with atomic hydrogen. Due to the difficulty associated with hydrofluoric acid treatments, rinsing with deionized water is generally performed next. The oxidizing species that may be present at the surface of the plate are then removed by annealing under hydrogen at moderate temperature (850-950° C.). Other techniques use this cleaning in situ, for example in a multichamber system.

A general problem with these high temperatures is that they require suitable equipment, at the level of both the epitaxy reactors and the plates undergoing the epitaxy; and the associated thermal budget, dependent on the amount of heat and the time, is particularly high, and therefore costly.

However, high temperatures (>1000° C.) are used to clean the surface of the silicon and allow for high deposition rates with very high quality epitaxy.

A reduced thermal budget (<900° C.) facilitates the development of very thin films and abrupt junctions required in the production of small elements.

Nevertheless, it is generally recognized that the quality of epitaxy diminishes with temperature.

However, the more the thermal budget is reduced, the greater the possibility is for using the epitaxy processes later in the printed circuit production sequence. Indeed, in a conventional process for producing printed circuits, the temperature may be reduced so as not to damage the structures already existing that cannot withstand high temperatures, in particular annealing.

Moreover, the developments in the production of semiconductor devices, in particular silicon-based devices, show that the complexity of production, the materials used, and the fineness of the patterns may require production methods at lower temperatures.

Furthermore, the state-of-the-art silicon technology, which is close to the limits allowed by the properties of silicon, may need to adopt complex architectures in which the silicon (Si)-based or silicon-germanium (SiGe)-based epitaxy are preferably used.

Therefore, there is a problem of compatibility between the low temperatures that are increasingly necessary and the quality required.

In addition, annealings with a significant thermal budget are a limitation to the introduction of epitaxy methods in processes for the production of advanced technology devices, for example CMOS-type. Typically, when structures are already present at the surface of a silicon plate, these annealings are not possible, in particular because they are not compatible with steep doping gradients, the metastable materials, or the “fragile” structures (for example of very small size), which may already be present on the silicon plate being produced.

Indeed, such annealings may promote, for example, surface diffusion phenomena, which reduce the quality of the printed circuit due to the formation of silicon “bumps”, as explained later in the description.

### SUMMARY

An embodiment of the invention is a low-temperature epitaxy method designed to obtain high-quality epitaxy.

To this end, an embodiment of the present invention proposes a method for low-temperature epitaxy at the surface of at least one plate of material based on pure silicon or a silicon alloy (SiGe, SiC, SiGeC . . . ), in a chemical vapor deposition (CVD) system, in particular a rapid thermal (RTCVD) system. The method includes at least the steps sequentially comprising:
loading the plate into the equipment, at a loading temperature,
preparing the surface for the deposition of new chemical species, and
after preparing the surface, performing the deposition under low-temperature epitaxy conditions (<750° C.),
   wherein the preparation of the surface includes a step of continuous passivation of the surface.

The step of preparation of the surface includes, for example, making the surface less subject (sensitive) to chemical contamination or to creep flow by surface diffusion.

With the passivation step, the surface of the plate is passivated, continuously, for example, by hydrogen and/or chlorine atoms, making the plate less sensitive to impurities, in particular to water vapor, which would react with the surface of the plate to result in silica (SiO2) and would thus diminish the quality of the epitaxy.

Thus, surprisingly, and contrary to the knowledge generally accepted, it has been found that the quality of the epitaxy need not deteriorate uniformly and rapidly when the annealing temperature is reduced.

And, with a method according to an embodiment of the invention, the annealing at a temperature greater than or equal to the deposition temperature is not necessary for obtaining quality epitaxy.

In this particular case, the method may even make it possible to eliminate this annealing step, which advantageously has a favorable effect on the thermal budget.

Also, the step of passivation of the surface may be performed by injection of an active gas, or active gas mixture, in which said active gas, or gas mixture, is chosen from the group including a hydrogen- and/or chlorine-based gas, for example HCl, and for example silicon, germanium or carbon chlorides or hydrides, in particular silane or dichlorosilane (DCS).

The injection of the active gas, or gas mixture, can be done at low temperature, typically below the deposition temperature, and preferably in the range of 400 to 500° C., which has the advantage of limiting the thermal budget.

Similarly, to limit the thermal budget, the loading of the plate may be advantageously done at low temperature, typically below the deposition temperature, and preferably in the range of 400 to 500° C.

As the injection of the active gas, or active gas mixture, and the loading of the plate are preferably done at the same temperature, the step of injection of the active gas, or gas mixture, is performed, at the latest, after the loading of the plate and, preferably, at the same time.

Finally, to prepare the deposition at the deposition temperature, the temperature in the chemical deposition equipment is increased from the temperature for loading the plate to the deposition temperature, preferably without exceeding the latter.

During this temperature increase, a method according to an embodiment of the invention may also include a step of desorption, as described later.

In one embodiment, the active gas, or active gas mixture, introduced in the step of passivation of the surface, is the same as the gas, or gas mixture, used for the deposition.

In another embodiment, the active gas, or active gas mixture, introduced in the step of passivation of the surface, is advantageously different from the gas, or gas mixture, used for the deposition.

For example, it is possible to use DCS as the active passivation gas, and silane as the deposition gas, or vice versa. Similarly, it is possible to use, for example, a silicon precursor as the active passivation gas, and a mixture (silicon precursor, germanium precursor) as the deposition gas, or vice versa.

The active gas, or gas mixture, introduced for the step of passivation of the surface, in addition to the passivation activity itself, also has a deposition, or etching, activity, depending on the type of gas used, of which the kinetics are dependent primarily on the gas(es) used.

In one embodiment, a method according to an embodiment of the invention uses this kinetic parameter to regulate the quality of the epitaxy.

For example, the active gas, or active gas mixture, used for the passivation may have much slower deposition kinetics than the deposition kinetics of the gas, or gas mixture, used for the deposition.

In another embodiment, the passivation step is performed by injection of an active gas mixture, in which, preferably, the mixture is adjusted, by adjustment means, for example flowmeters, so as to obtain near-zero deposition kinetics, said mixture containing at least one etching gas and a deposition gas.

As mentioned above, the step of preparation of the surface may include at least one pre-cleaning of the plate surface, ex situ or in situ, so as to remove the oxides, for example by a hydrofluoric acid treatment, in particular of the HF-last-type.

In another embodiment, the method may include a step of annealing in temperature, before the deposition, at a temperature greater than that of the deposition.

A method according to an embodiment of the invention may be applied in particular to epitaxy technologies for plates of 300 mm.

An embodiment of the invention also relates to the use of the method described above in order to reduce creep flow phenomena by surface diffusion of structures of the plate undergoing the epitaxy.

In this case, the use of a method according to an embodiment of the invention makes it possible to produce ultrathin layers of silicon on insulator, in particular having a thickness of 15 to 50 Å.

### BRIEF DESCRIPTION OF THE DRAWINGS

Other features and advantages will become clearer from the following description provided as an illustrative and non-limiting example, in reference to the appended figures.

FIG. 1a shows a diagram of the thermal cycles in conventional low-temperature epitaxy with annealing.

FIG. 1b shows a diagram of the thermal cycles according to an embodiment of the invention.

FIG. 2a shows a diagrammatic cross-section of the formation of sources/drains raised by conventional selective epitaxy with surface diffusion phenomena, just before the actual deposition.

FIG. 2b shows a diagrammatic cross-section of the formation of sources/drains raised by selective epitaxy according to an embodiment of the invention, just before the actual deposition.

FIG. 3a shows a diagrammatic cross-section of etched sides after a standard low-temperature epitaxy method by deposition of SiGe material.

FIG. 3b shows a diagrammatic cross-section of etched sides after an epitaxy method by deposition of SiGe material according to an embodiment of the invention.

### DETAILED DESCRIPTION

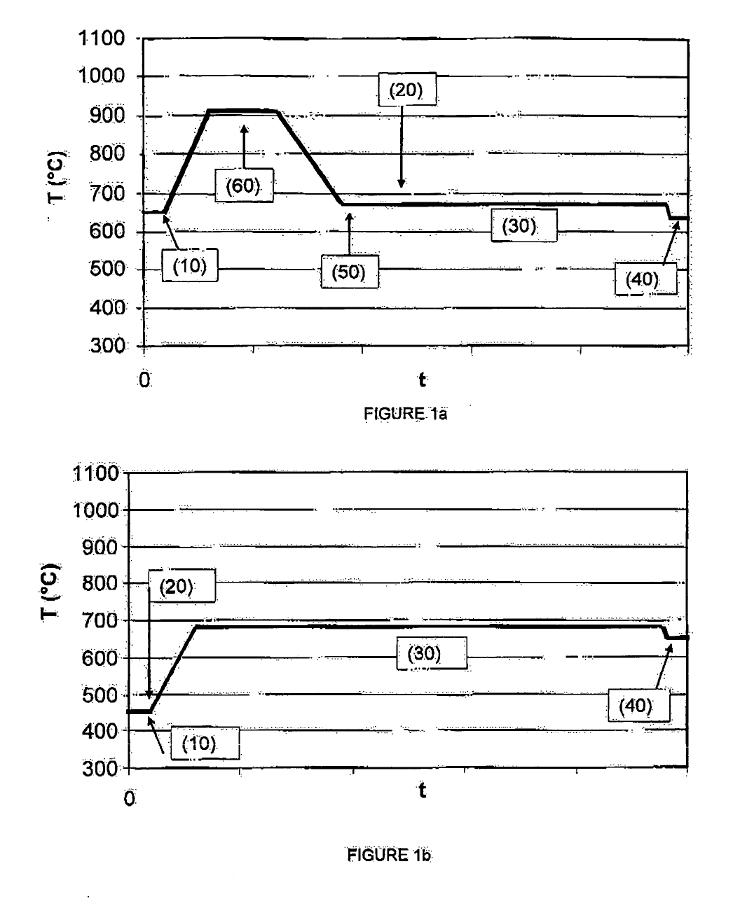

As shown in FIG. 1a, according to an arbitrary time t, a conventional low-temperature epitaxy method includes a thermal cycle during which the plate is first loaded (10) into CVD equipment. After this loading, a high-temperature annealing (60) is performed, generally under hydrogen, typically to remove the oxides. After temperature stabilization (50), the active gas, or gas mixture, (20) is injected for the deposition (30) of new species, so as to ultimately unload (40) the plate from the equipment.

In an embodiment of the invention, FIG. 11b, according to an arbitrary time t, the method for low-temperature epitaxy at the surface of at least one plate made of a material based on pure silicon or silicon alloy (SiGe, SIC, SiGeC . . . ), in a chemical vapor deposition (CVD) system, in particular a rapid thermal (RTCVD) system, includes at least one step of loading (10) the plate into the equipment, at a loading temperature.

The loading of the plate is done at low temperature, typically at a temperature below the deposition temperature, and preferably in the range of 400 to 500° C., so as to reduce the thermal budget.

According to an embodiment of the invention, the active gas, or active gas mixture, (20) is injected so as to passivate the surface of the plate, for subsequent deposition, which makes it possible to prepare the surface for a deposition of new chemical species.

This active gas, or active gas mixture, injection is preferably done at low temperature, typically below the deposition temperature, preferably in the range of 400 to 500° C. In an embodiment, the injection (20) is done at the loading temperature.

The temperature in the chemical deposition equipment is then increased from the temperature for loading the plate to the deposition temperature, at which the deposition (30) of new chemical species takes place. In an embodiment, the temperature in the equipment does not exceed that of the deposition.

In another embodiment, included during this increase in temperature, before reaching the deposition temperature, a desorption step, so as to remove the residual water vapor, hydrocarbons, and so on. This desorption step is performed by a relatively slow increase in the temperature, by a temperature pause of several seconds, or by a lower pressure and an increased pumping speed.

Finally, after the preparation of the surface, the deposition (30) is performed under low-temperature epitaxy conditions (<750° C.).

According to an embodiment of the invention, the preparation of the surface includes a step of continuous passivation of the surface, so as to make the surface of the plate less sensitive to the impurities, and/or to make the surface diffusions occur more slowly.

The step of passivation of the surface is performed by injection of an active gas, or gas mixture. The term active means that the gas, or the gas mixture, has an effect on the surface of the plate. In particular, it is easily dissociated on the silicon surface so as to leave an adsorbed atomic layer.

Typically, the active gas, or gas mixture, is chosen from the group including a hydrogen- and/or chlorine-based gas, for example HCl, and silicon, germanium or carbon chlorides or hydrides, in particular silane or dichlorosilane (DCS).

Thus, the atomic chloride and/or hydrogen are adsorbed at the surface of the plate and passivate it, in particular against oxidation.

The active gas, or active gas mixture, introduced for the step of passivation of the surface can be a conventional gas, or gas mixture, used for the deposition.

However, an active gas, or active gas mixture, different from that used for the deposition is typically used.

For example, it is possible to choose DCS as the active gas, and silane as the deposition gas, or vice versa. Alternatively, it is possible to use a silicon precursor as the active gas, and a mixture (silicon precursor, germanium precursor) as the deposition gas, or vice versa.

Thus, in one embodiment, an active gas, or gas mixture, is used for the passivation, of which the deposition kinetics are much slower than the deposition kinetics of the gas, or gas mixture, used for the deposition.

In this way, it is possible to alter the respective kinetics so that the silicon atoms deposited during the passivation do not diminish the quality of the subsequent deposition.

In some cases, it is even desirable to minimize the deposition during the passivation step. To this end, the passivation step is performed, for example, by injection of an active gas mixture in which the mixture is adjusted, by adjustment means, so as to obtain near-zero deposition kinetics, said mixture containing at least one etching gas and a deposition gas.

It is possible to take, for example, HCl as the etching gas, wherein the etching removes silicon atoms from the plate.

According to an embodiment of the invention, the plate is continuously passivated. It is therefore suitable for the step of injection of the active gas, or gas mixture, to be performed, at the latest, after the loading of the plate.

In one embodiment, the surface preparation step includes at least one pre-cleaning of the plate surface, ex situ or in situ, so as to remove the oxides, for example by a hydrofluoric acid treatment. For example, it is possible to use an “HF-last”-type cleaning process.

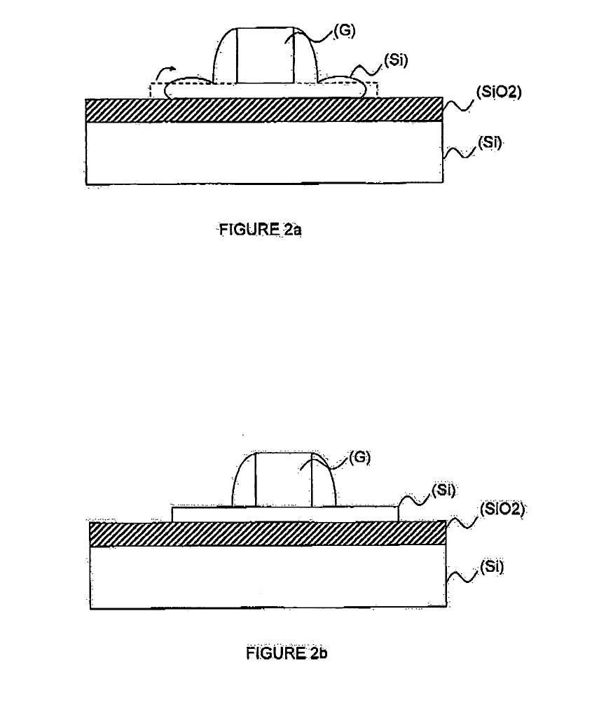

In conventional low-temperature epitaxy methods, the annealing generates creep flow phenomena by surface diffusion, as shown in FIG. 2a. Under the effect of the heat, the morphology of a structure (component or the like) at the surface of a plate does not retain its ideal shape, shown with dotted lines, but tends to form bumps.

This formation of silicon (Si) bumps at the edge of a structure (G) diminishes the quality of the final structure/component/printed circuit. It can even lead to the destruction of the thinnest structures.

According to an embodiment of the invention, the use of the above-described method makes it possible to reduce the creep flow phenomena by surface diffusion of structures of the plate undergoing epitaxy (FIG. 2b).

Similarly, it is possible to use a method according to an embodiment of the invention to perform epitaxy on silicon with anisotropic etching.

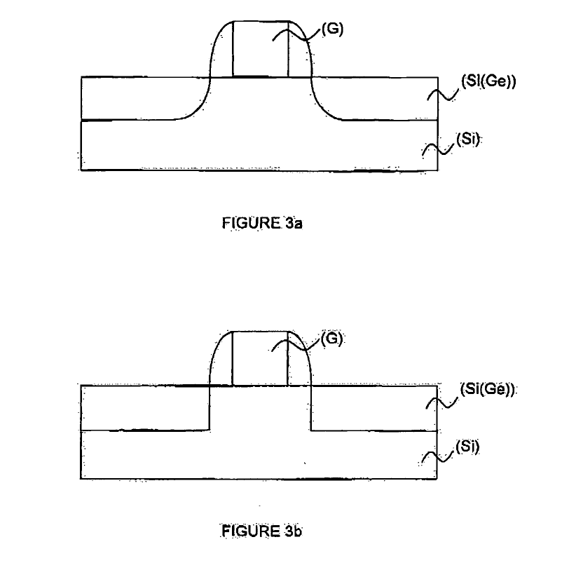

In a conventional low-temperature epitaxy method, FIG. 3a, the etching profile may be largely modified. However, the shape of the sides is involved to a high degree at the level of the constraint transmitted on the gate (G).

According to an embodiment of the invention, FIG. 3b, the etching profile is retained. The structure, for example an MOS transistor, therefore has a better performance.

With a method according to an embodiment of the invention, it may be possible to use low-temperature epitaxy to produce ultrathin silicon on insulator layers, in particular having a thickness of 15 to 50 Å.

An integrated circuit formed by a method such as described above in conjunction with FIG. 1b may be included in an electronic system, such as a computer system.

From the foregoing it will be appreciated that, although specific embodiments of the invention have been described herein for purposes of illustration, various modifications may be made without deviating from the spirit and scope of the invention.

1. Method for low-temperature epitaxy at the surface of at least one plate made of a pure silicon- or silicon alloy (SiGe, SiC, SiGeC . . . )-based material, in a chemical vapor deposition system, in particular a rapid thermal system, which method includes at least the steps sequentially comprising:
loading the plate into the equipment, at a loading temperature,
preparing the surface for the deposition of new chemical species, and
after preparing the surface, performing the deposition under low-temperature epitaxy conditions (<750° C.),
wherein the preparation of the surface includes a step of continuous passivation of the surface.

2. Epitaxy method according to claim 1, in which the step of passivation of the surface is performed by injection of an active gas, or active gas mixture, in which said active gas, or active gas mixture, is chosen from the group including a hydrogen- and/or chlorine-based gas, for example HCl, and for example silicon, germanium or carbon chlorides or hydrides, in particular silane or dichlorosilane (DCS).

3. Epitaxy method according to claim 2, in which the injection of the active gas, or active gas mixture, is done at low temperature, typically below the deposition temperature, and preferably in the range of 400 to 500° C.

4. Epitaxy method according to claim 1, in which the loading of the plate is done at low temperature, typically below the deposition temperature, and preferably in the range of 400 to 500° C.

5. Epitaxy method according to claim 1, in which the temperature in the chemical deposition system is increased from the temperature for loading the plate to the deposition temperature, without exceeding the latter.

6. Epitaxy method according to claim 5, also including a step of desorption, during the temperature increase.

7. Epitaxy method according to claim 1 in which the active gas, or active gas mixture, introduced in the step of passivation of the surface, is different from the gas, or gas mixture, used for the deposition, for example DCS as the active gas, and silane as the deposition gas; and, for example, a silicon precursor as the active gas, and a mixture (silicon precursor, germanium precursor) as the deposition gas, or vice versa.

8. Epitaxy method according to claim 1, in which the active gas, or active gas mixture, used for the passivation has much slower deposition kinetics than the deposition kinetics of the gas, or gas mixture, used for the deposition.

9. Epitaxy method according to claim 1, in which the passivation step is performed by injection of an active gas mixture, and in which the mixture is adjusted, by adjustment means so as to obtain near-zero deposition kinetics, said mixture containing at least one etching gas and a deposition gas.

10. Epitaxy method according to claim 1, in which the active gas, or active gas mixture, injection step is performed, at the latest, after the loading of the plate.

11. Use of the method according to claim 1, to reduce creep flow phenomena by surface diffusion of structures of the plate undergoing the epitaxy.

12. Use of the method according to claim 1 for the production of ultrathin layers of silicon on insulator, in particular having a thickness of 15 to 50 Å.

13. A method, comprising:
flowing a first gas into a chamber at a first temperature to passivate a surface of a silicon substrate disposed within the chamber;
heating the chamber to a second temperature;
flowing the first gas into the chamber while heating the chamber; and
growing an epitaxial layer on the surface of the substrate while the chamber is at the second temperature.

14. The method of claim 13 wherein the first gas comprises a mixture of gases.

15. The method of claim 13 wherein the first gas comprises hydrogen.

16. The method of claim 13 wherein the first gas comprises chlorine.

17. The method of claim 13 wherein the first temperature is between 400°-500° C.

18. The method of claim 13 wherein the substrate comprises pure silicon.

19. The method of claim 13 wherein the substrate comprises a silicon alloy.

20. The method of claim 13 wherein the second temperature is less than 750° C.

21. The method of claim 13 wherein growing the epitaxial layer comprises:
continuing to flow the first gas into the chamber; and
growing the epitaxial layer from the first gas.

22. The method of claim 13 wherein growing the epitaxial layer comprises:
flowing the first gas and a second gas into the chamber; and
growing the epitaxial layer from the second gas.

23. The method of claim 13 wherein growing the epitaxial layer comprises:
discontinuing the flow of the first gas into the chamber;
flowing a second gas into the chamber; and
growing the epitaxial layer from the second gas.

24. The method of claim 13, further comprising loading the substrate into the chamber while the chamber is at the first temperature.

25. The method of claim 13, further comprising cleaning the surface of the substrate before flowing the first gas.

26. The method of claim 13, further comprising desorping the chamber while heating the chamber to the second temperature.

27. A method, comprising:
causing a temperature within a chamber in which a substrate is disposed to be no greater than a deposition temperature that is 750° C. or less;
flowing a gas into the chamber to passivate a surface of the substrate;
causing the temperature within the chamber to equal the deposition temperature; and
growing an epitaxial layer on the surface of the substrate while the temperature within the chamber equals the deposition temperature.

28. The method of claim 27 wherein causing the temperature to equal the deposition temperature comprises heating the chamber to the deposition temperature.

29. The method of claim 27 wherein flowing the gas comprises flowing the gas into the chamber while causing the temperature within the chamber to equal the deposition temperature.

30. The method of claim 27 wherein the substrate comprises silicon.
